(19) United States
(12) Patent Application Publication
(10) Pub. No.: US 2007/0181954 A1
(43) Pub. Date: Aug. 9, 2007

(54) Semiconductor device and method of manufacture thereof

(76) Inventor: Kota Oikawa, Kyoto (JP)

Correspondence Address: MCDERMOTT WILL & EMERY LLP, 600 13TH STREET, NW, WASHINGTON, DC, 20005-3096, US

(21) Appl. No.: 11/703,671

(22) Filed: Feb. 8, 2007

(30) Foreign Application Priority Data
Feb. 8, 2006 (JP) 2006-031538

(51) Int. Cl. H01L 29/76

(52) U.S. Cl. 257/382

(57) ABSTRACT

The semiconductor device of present invention is provided with an impurity diffusion region formed in the surface part of a semiconductor layer and a metal silicide layer formed in the surface part of the impurity diffusion region. An interlayer insulating film is formed on the metal silicide layer, and a contact plug that passes through the interlayer insulating film and is electrically connected with the metal silicide layer is formed. The contact plug passing through the interlayer insulating film is formed in a region where the metal silicide layer has a sufficient film thickness, and a recess is formed in the metal silicide layer at the contact hole bottom. Moreover, the contact plug has a projection fitting to the recess of the metal silicide layer in a part of a contact surface with the metal silicide layer.

### CROSS-REFERENCE TO RELATED APPLICATION

The present application claims the benefit of patent application number 2006-031538, filed in Japan on Feb. 8, 2006, the subject matter of which is incorporated herein by reference.

### BACKGROUND OF THE INVENTION

1. Field of the Invention

The present invention relates to a semiconductor device and a method of manufacture thereof, and particularly to a semiconductor device having a metal silicide layer formed at the surface of an impurity diffusion region and a method of manufacture thereof.

2. Description of the Related Art

The junction depth of an impurity diffusion region has been made shallow with recent micro-miniaturization of semiconductor devices. In a semiconductor device provided with such a shallow impurity diffusion region, nickel silicide (NiSi) that has small silicidation erosion depth and is capable of silicidation at a lower temperature has been adopted as a metal silicide layer.

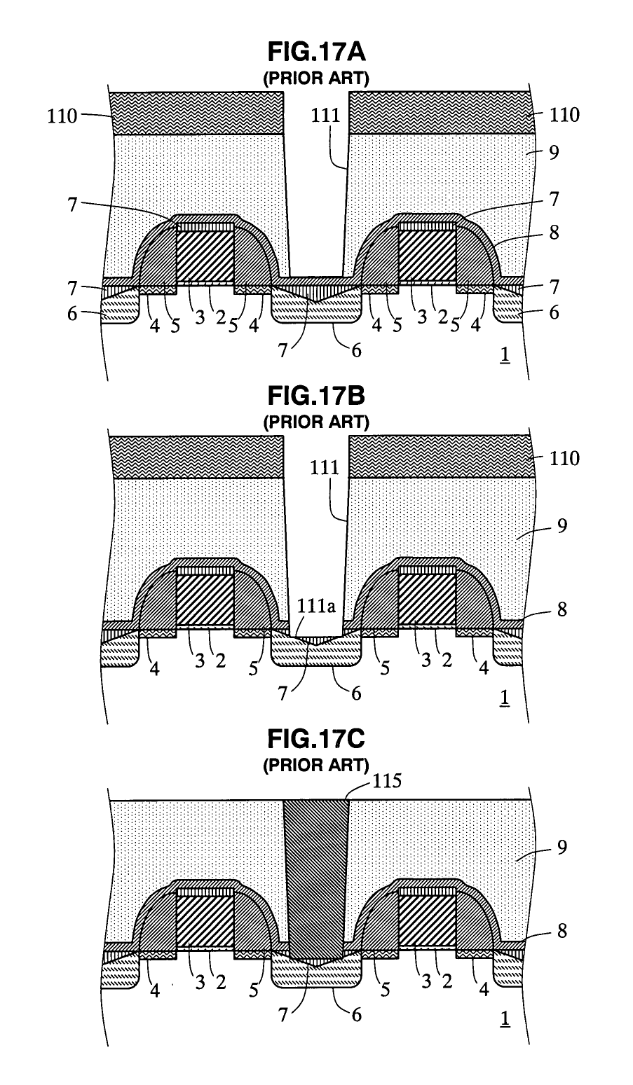

FIGS. 17A to 17C are process sectional drawings showing a prior formation process of a contact using nickel silicide. In FIGS. 17A to 17C, two transistors are formed by a well-known salicide (Self-aligned Silicide) process in a region divided by element isolation (non-illustrated) on a semiconductor substrate 1 made of silicon.

As shown in FIG. 17A, each transistor has gate electrodes 3 made of polysilicon and formed on the semiconductor substrate 1 via a gate insulating film 2. Each gate electrode 3 has sidewall spacers 5 on both sides and an extension region consisting of a low-concentration impurity diffusion region 4 under the sidewall spacers 5. A common drain region consisting of a high-concentration impurity diffusion region 6 is arranged between the gate electrodes 3, and a contact to be formed on the drain region. A source region consisting of a high-concentration impurity diffusion region 6 is arranged on opposite side across the gate electrodes 3 from the drain region. Moreover, a nickel silicide layer 7 is formed in a self-aligning manner upside of the gate electrodes 3 and upside of the high-concentration impurity diffusion region 6.

In a contact forming process, as shown in FIG. 17A, a stopper film 8 consisting of a silicon nitride film or the like is deposited by CVD (Chemical Vapor Deposition) method on the semiconductor substrate 1 formed with the above transistors. An interlayer insulating film 9 consisting of a silicon oxide film or the like is deposited by CVD method on the stopper film 8, and the upside of the insulating film 9 is flattened by CMP (Chemical Mechanical Polishing) method or etch-back method. Next, a resist pattern 110 having an opening at a contact formation position is formed on the insulating film 9 by a well-known photolithographic technique. A contact hole 111 passing through the insulating film 9 is then formed by anisotropic dry etching with the resist pattern 110 as a mask. In this etching process, the stopper film 8 functions as an etching stopper. Therefore, the anisotropic dry etching stops in a state of exposing the stopper film 8 to the bottom of the contact hole 111.

Successively, as shown in FIG. 17B, the stopper film 8 exposed to the bottom of the contact hole 111 is removed by dry etching, and the nickel silicide layer 7 is exposed to the bottom of the contact hole 111. Subsequently, the resist pattern 110 is removed by ashing, etc. and then, as shown in FIG. 17C, a contact plug 115 electrically connected with the nickel silicide layer 7 is formed by filling a conductor into the contact hole 111 (e.g., see Japanese Laid-Open Patent Application 2001-196327, etc.).

### SUMMARY OF THE INVENTION

The above nickel silicide (NiSi) is a metastable phase. Therefore, heat treatment or the like in the manufacturing process is usually carried out at a temperature where nickel silicide (NiSi) is not phase-changed to nickel disilicide (NiSi₂) being a stable phase. However, the phase change locally occurs due to the ambient structure of a region formed with the nickel silicide layer 7 even in such a manufacturing process. For example, the phase change tends to easily occur in the nickel silicide between the gate electrodes 3 provided at a narrow spacing as shown in FIGS. 17A to 17C. Such a local phase change is supposed to occur due to the surface state or stress, etc. of the semiconductor substrate.

It has been known that when nickel monosilicide (NiSi) formed at the surface of a p-type silicon substrate phase-changes to nickel disilicide (NiSi₂), nickel disilicide grows along a crystal plane ((111) plane) of the silicon substrate. Therefore, when the nickel silicide layer 7 is formed between the two gate electrodes 3, the cross-sectional shape of the nickel silicide layer 7 becomes a wedge shape in case the spacing of the gate electrodes 3 is wide, particularly, it becomes an inverted triangle in case the spacing of the gate electrodes 3 is as narrow as 140 nm or less (see FIG. 17B).

As described above, the nickel silicide layer 7 is exposed to the bottom of the contact hole 111 by dry etching of the stopper film 8. In dry etching of the stopper film 8, an over etching is performed so that the stopper film 8 is completely removed in the plane of the semiconductor substrate 1, and a part of the nickel silicide layer 7 is also etching removed.

At this time, if the nickel silicide layer 7 is in the shape of inverted triangle, a part of the bottom of the contact hole 111 passes through the nickel silicide layer 7 and reaches the high-concentration impurity diffusion region 6. In this case, the high-concentration impurity diffusion region 6 exposes to the bottom 111a of the contact hole 111.

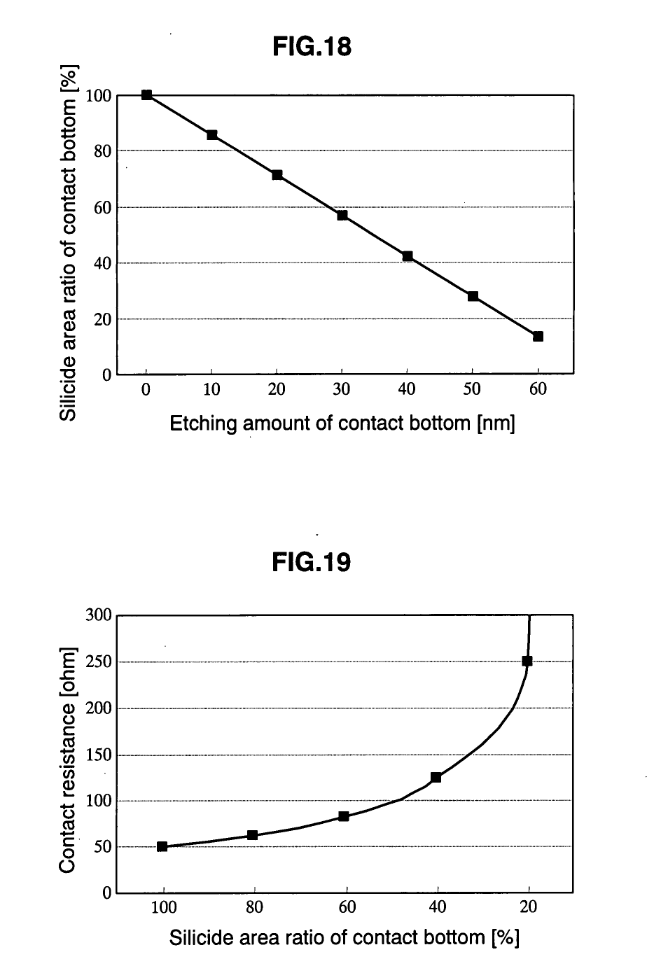

FIG. 18 is a graph showing a relationship between the etching amount of the nickel silicide layer 7 and the silicide area ratio in case the diameter of the contact hole at the surface of the nickel silicide layer 7 is 80 nm. Here, the silicide area ratio is a proportion occupied by the nickel silicide layer 7 to the total area of the bottom 111a of the contact hole 111. As shown in FIG. 18, it may be understood that the silicide area ratio reduces by about 20% even in case the etching amount is about 10 nm. If the area ratio thus reduces, the contact area of the contact plug 115 and the nickel silicide layer 7 reduces, thus such a problem with increasing contact resistance arises.

FIG. 19 is a graph showing a relationship between the silicide area ratio and the contact resistance at the surface of the nickel silicide layer 7 in case the contact hole diameter is 80 nm. As shown in FIG. 19, it may be understood that if the area ratio reduces, the contact resistance suddenly increases. For example, if the area ratio reduces by 20% (the etching amount is 10 nm), the contact resistance becomes 1.25 times as much as in case the silicide area ratio is 100%.

When the cross-sectional shape of the nickel silicide layer 7 is an invented triangle, the diameter of the contact hole bottom 111a may be reduced so that the high-concentration impurity diffusion region 6 is not exposed to the contact hole bottom 111a. However, this method has no effect on inhibiting the rise of contact resistance because the contact area of the contact plug 115 and the nickel silicide layer 7 decreases. The exposure of the high-concentration impurity diffusion region 6 at the contact hole bottom 111a may also be inhibited by reducing the etching amount of the nickel silicide layer 7. However, a dispersion in film thickness of the stopper film 8 or the etch rate in stopper film etching exists in the plane of the semiconductor substrate 1. Therefore, if the etching amount is reduced, the stopper film 8 is not completely removed, the occurrence rate of poor contact increases and the manufacturing yield lowers.

The present invention was proposed in view of the above circumstances, and its purpose is to provide a semiconductor device that may inhibit the exposure of a high-concentration impurity diffusion region at the contact hole bottom and may form a low-resistance contact with good yield and a manufacturing method of the semiconductor device.

The present invention adopts the following means to achieve the abovementioned object. First, the semiconductor device premised on the present invention is provided with an impurity diffusion region formed in the surface part of a semiconductor layer and a metal silicide layer formed in the surface part of the impurity diffusion region. An interlayer insulating film is formed on the metal silicide layer, and a contact plug passing through the interlayer insulating film and electrically connected with the metal silicide layer is formed. Then, the semiconductor device relating to the present invention is provided with the metal silicide layer having a recess at the contact surface with a contact plug and the contact plug having a projection fitted to the recess in a part of the contact surface with the metal silicide layer. In the structure, a multi-step structure may be adopted for the recess. The contact surface of the metal silicide layer with the contact plug may also be made into a concave curved surface.

This structure enables increasing the contact area of the contact plug and the metal silicide layer. Moreover, this enables to prevent the high-concentration impurity diffusion region from exposing to the contact surface of the contact plug and the nickel silicide layer by arranging the projection of the contact plug at a position where the nickel silicide layer has sufficient thickness even when the nickel silicide layer grows along the crystal surface of the silicon substrate.

On the one hand, the present invention may provide a manufacturing method of semiconductor device embodying the above semiconductor device in another view of point. Namely, in the manufacturing method of semiconductor device relating to the present invention, first, an impurity diffusion region is formed in the surface part of a semiconductor layer. A metal silicide layer is formed in the surface part of the impurity diffusion region. An interlayer insulating film is formed on the semiconductor layer formed with the metal silicide layer. Next, a mask pattern having an opening at a contact plug formation position is formed on the interlayer insulating film. A through hole is formed in the interlayer insulating film by etching via the mask pattern. A recess is formed in the metal silicide layer by etching via the through hole. Subsequently, the diameter of the through hole is expanded, and a contact plug is formed by filling a conductor into the expanded through hole. The recess of the metal silicide layer may be simultaneously formed, e.g., by etching at the time of forming the through hole in the interlayer insulating film.

After the formation of the through hole, a spacer may also be formed at the inner wall of the through hole. In this case, the recess of the metal silicide layer is formed by etching via the through hole formed with the spacer. The spacer of the through hole is removed after the formation of the recess, thereby the diameter of the through hole is expanded. The formation of the recess and the expansion of the through hole may be alternately repeated and performed multiple times. In this case, a recess having a multi-step structure is formed at the surface of the metal silicide layer.

On the other hand, the recess of the metal silicide layer may also be formed by providing a pattern for controlling the diameter of bottom of the through hole after the formation of the metal silicide layer in place of formation of the spacer. In this case, an interlayer insulating film is formed on the semiconductor layer formed with the control pattern, and the through hole is formed in a region including the control pattern. Then, a recess is formed in the metal silicide layer by etching via the control pattern. The control pattern is removed after the formation of the recess, and the diameter of the through hole is expanded. Such a control pattern may be formed as the sidewall of the gate electrode, e.g., under a condition that two gate electrodes are opposite arranged by interposing the through hole.

In the above structure, a concave curved surface may also be formed in a region including the contact surface of the metal silicide layer with the contact plug by performing an isotropic etching in the semiconductor before the formation of the metal silicide layer. It enables increasing the contact area of the contact plug and the metal silicide layer. For example, the isotropic etching may be performed with the sidewall of the gate electrode as a mask under such a condition that two gate electrodes are opposite arranged by interposing the through hole. The isotropic etching may also be performed by wet etching.

The concave curved surface may also be formed by removing a part of the metal silicide layer by an isotropic etching via the expanded through hole after the expansion of the through hole diameter. The isotropic etching may also be performed by wet etching.

By the above techniques, the recess is formed in a region where the nickel silicide layer has a sufficient thickness, and the contact plug fitted to a part of the bottom is formed in the recess. Accordingly, the present invention enables to prevent the high-concentration impurity diffusion region from exposing to the contact surface of the contact plug and the metal silicide layer. This also enables to ensure the contact surface area of the contact plug and the metal silicide layer because the through hole diameter is larger than the region formed with the recess. As a result, a reduction of manufacturing yield due to the rise of contact resistance is inhibited.

As described above, the present invention enables inhibiting the exposure of the semiconductor substrate at the bottom of the contact hole when the contact hole is formed in the interlayer insulating film. It also enables to ensure a sufficient contact surface area of the contact plug and the metal silicide layer. Namely, the present invention enables inhibiting a reduction of manufacturing yield due to the rise of contact resistance and manufactures a low-resistance contact in a good yield.

The foregoing and other objects, features, aspects and advantages of the present invention will become more apparent from the following detailed description of the present invention when taken in conjunction with the accompanying drawings.

### BRIEF DESCRIPTION OF THE INVENTION

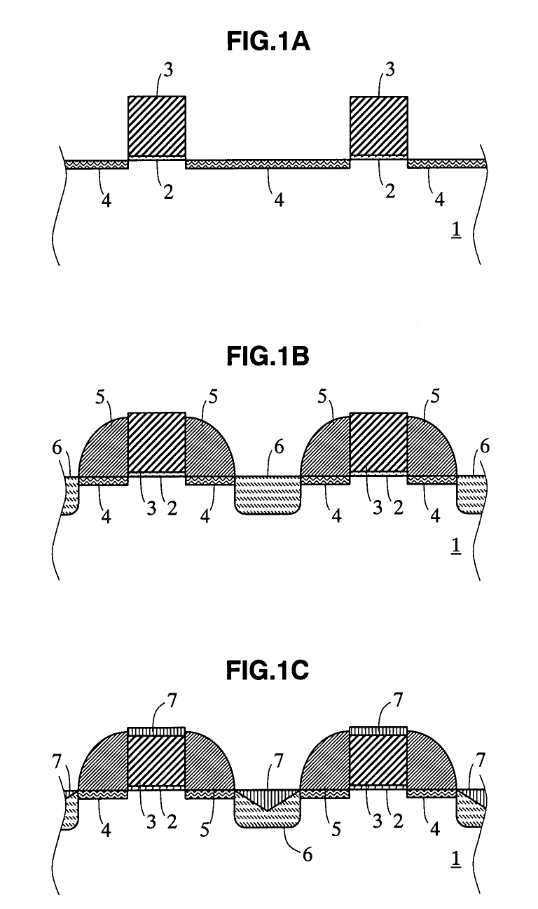

FIGS. 1A to 1C are sectional views showing a manufacturing process of a semiconductor device in Embodiment 1 of the present invention.

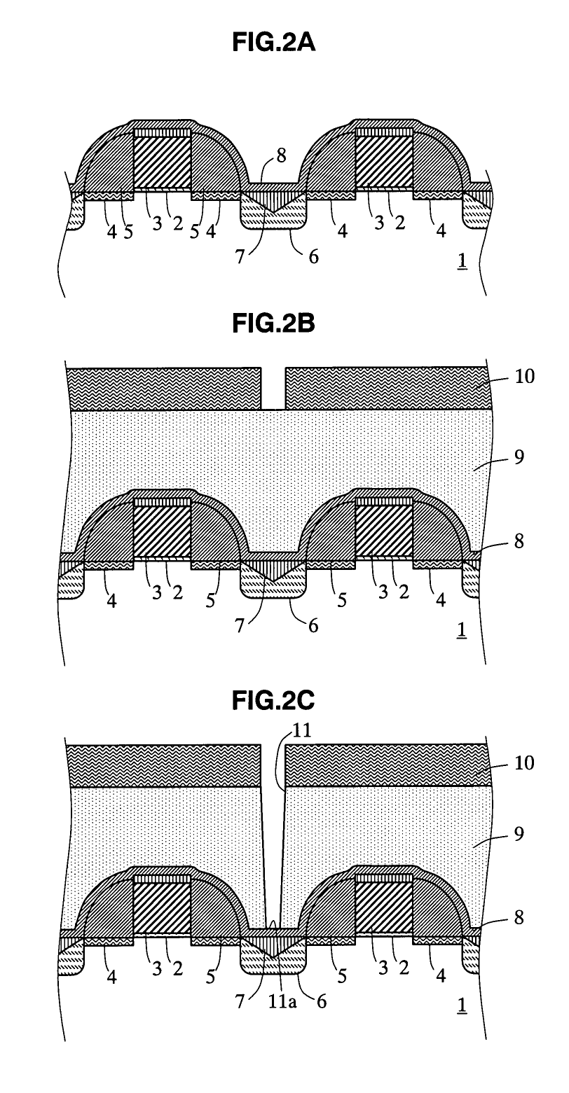

FIGS. 2A to 2C are sectional views showing a manufacturing process of a semiconductor device in Embodiment 1 of the present invention.

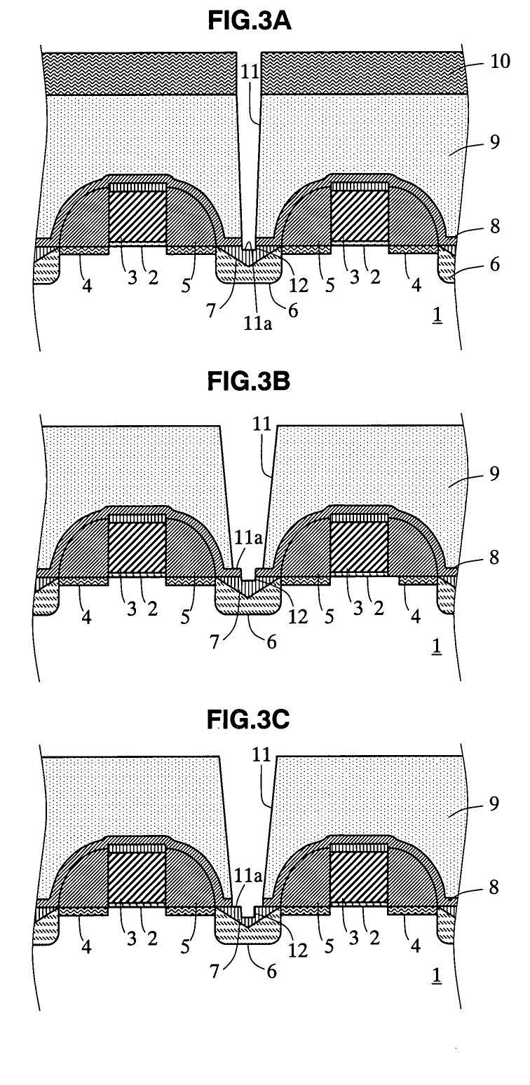

FIGS. 3A to 3C are sectional views showing a manufacturing process of a semiconductor device in Embodiment 1 of the present invention.

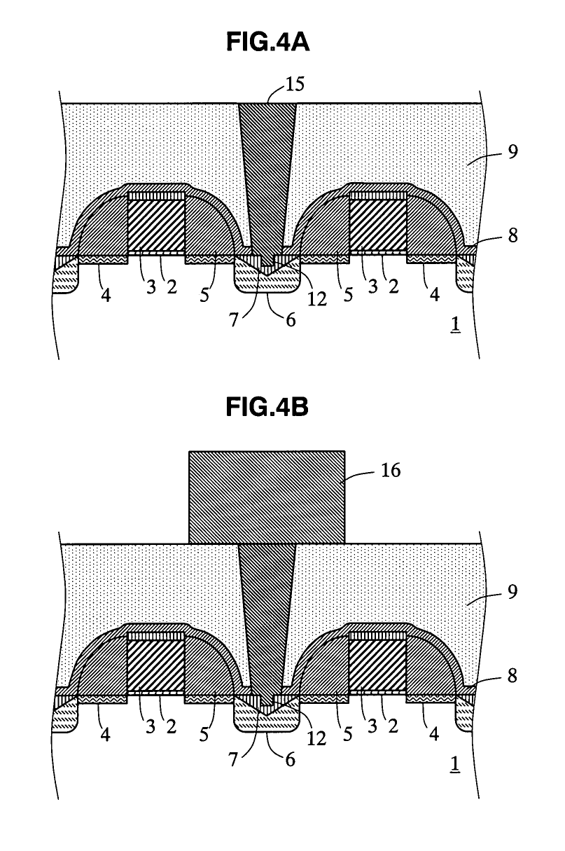

FIGS. 4A and 4B are sectional views showing a manufacturing process of a semiconductor device in Embodiment 1 of the present invention.

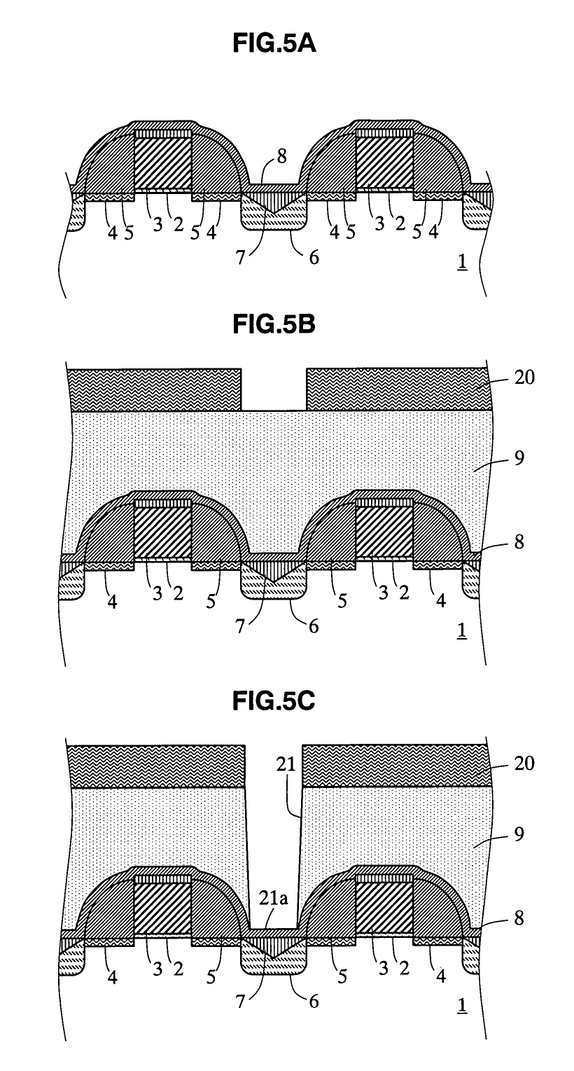

FIGS. 5A to 5C are sectional views showing a manufacturing process of a semiconductor device in Embodiment 2 of the present invention.

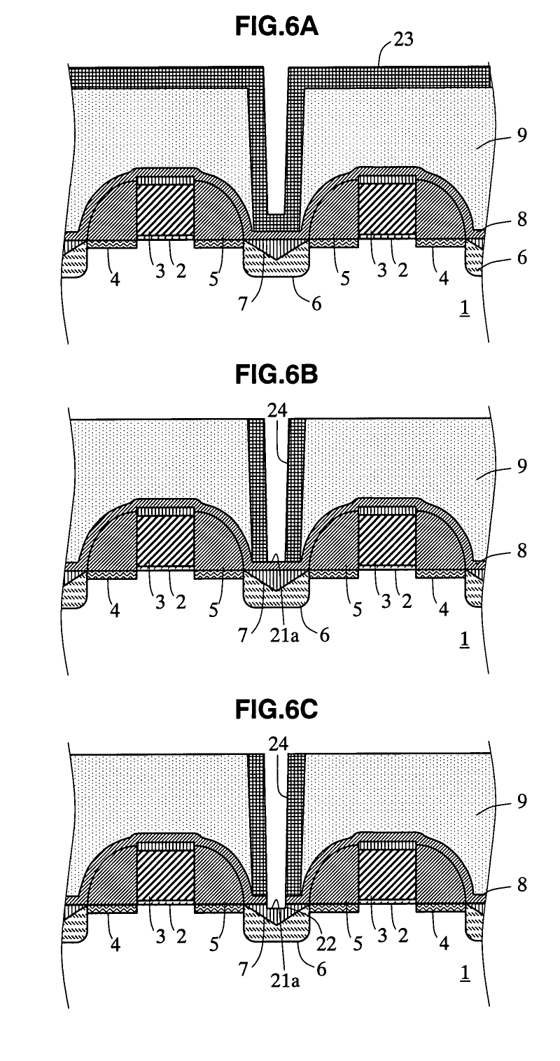

FIGS. 6A to 6C are sectional views showing a manufacturing process of a semiconductor device in Embodiment 2 of the present invention.

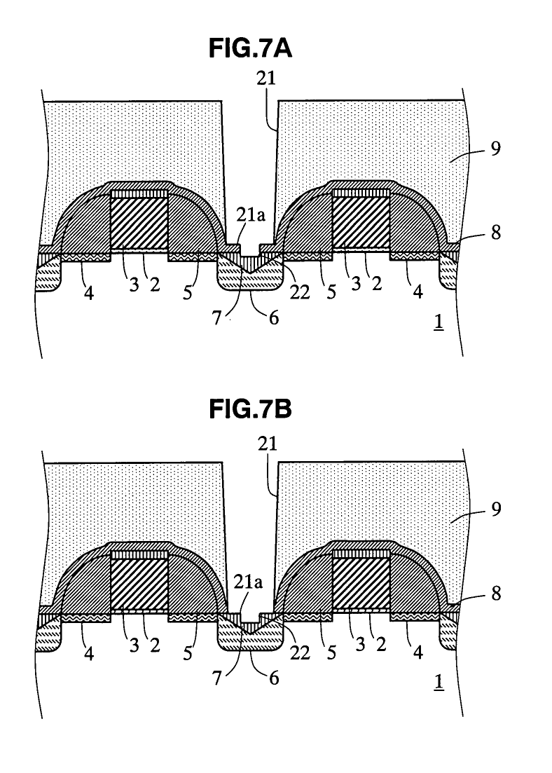

FIGS. 7A and 7B are sectional views showing a manufacturing process of a semiconductor device in Embodiment 2 of the present invention.

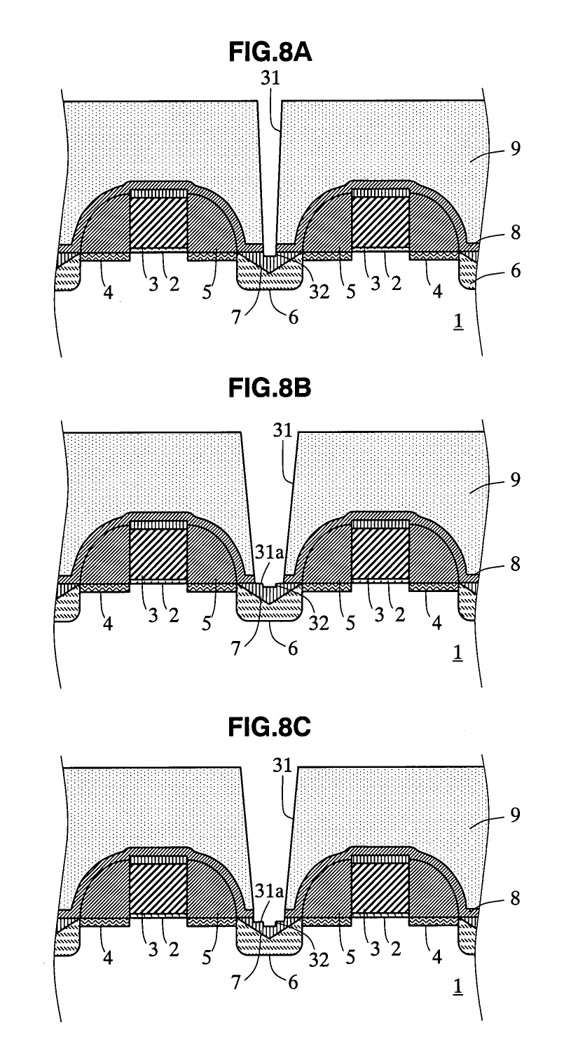

FIGS. 8A to 8C are sectional views showing a manufacturing process of a semiconductor device in Embodiment 3 of the present invention.

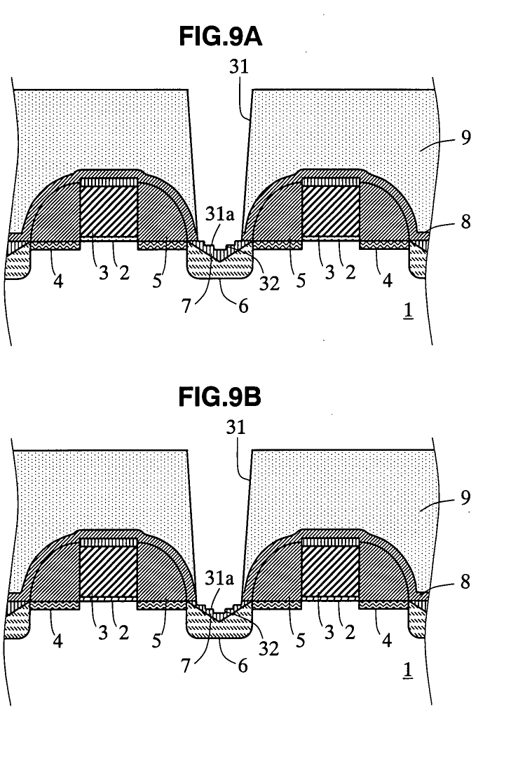

FIGS. 9A and 9B are sectional views showing a manufacturing process of a semiconductor device in Embodiment 3 of the present invention.

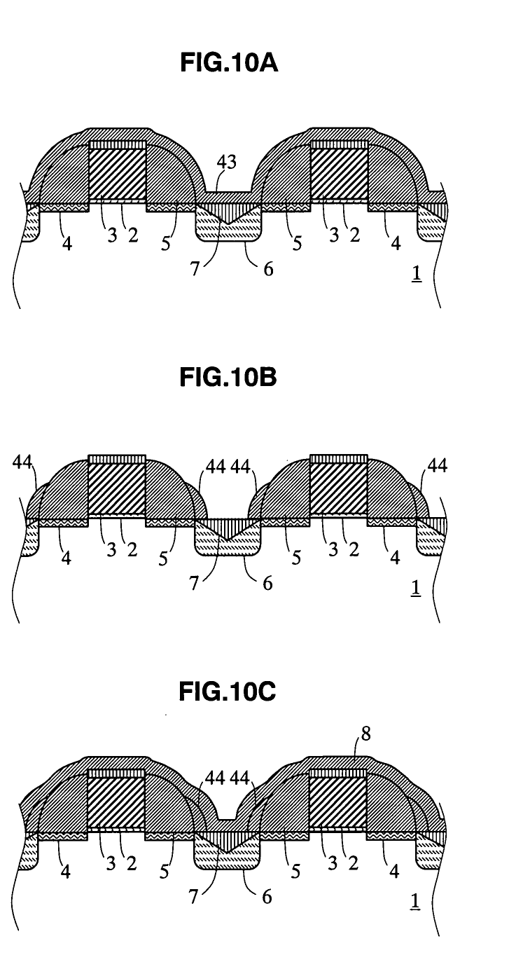

FIGS. 10A to 10C are sectional views showing a manufacturing process of a semiconductor device in Embodiment 4 of the present invention.

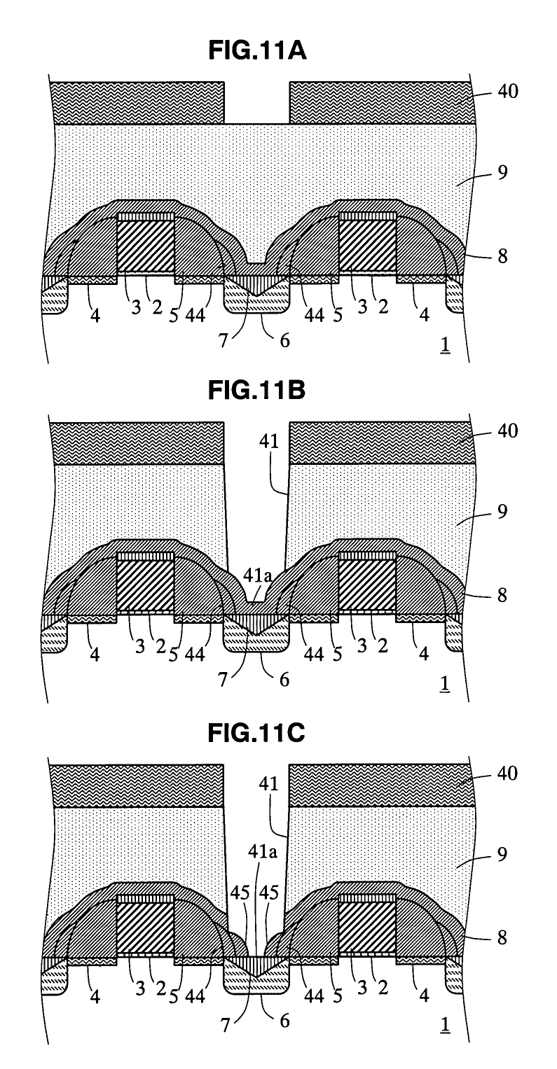

FIGS. 11A to 11C are sectional views showing a manufacturing process of a semiconductor device in Embodiment 4 of the present invention.

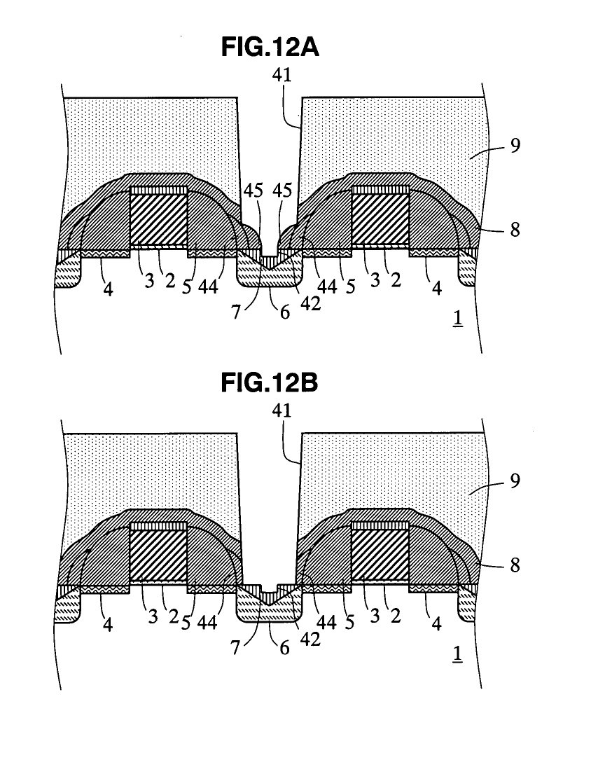

FIGS. 12A and 12B are sectional views showing a manufacturing process of a semiconductor device in Embodiment 4 of the present invention.

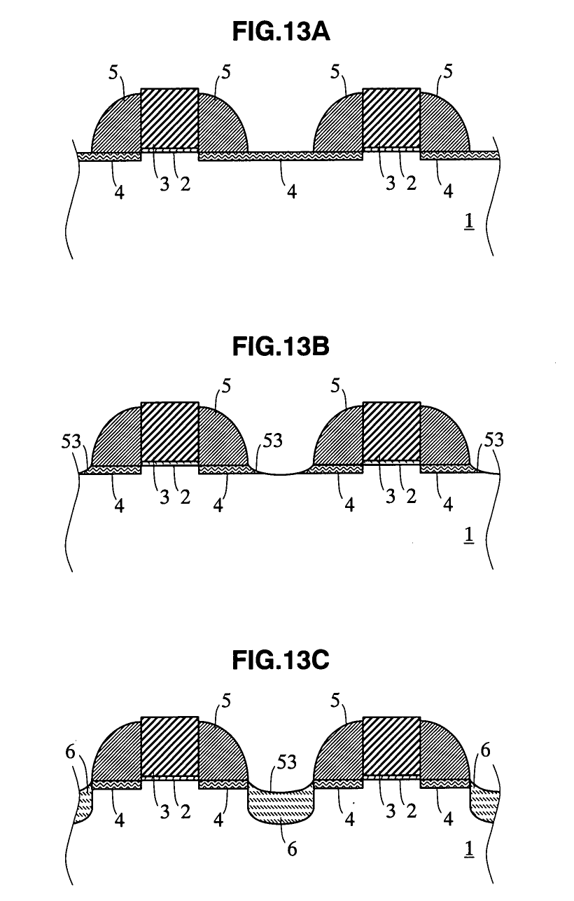

FIGS. 13A to 13C are sectional views showing a manufacturing process of a semiconductor device in Embodiment 5 of the present invention.

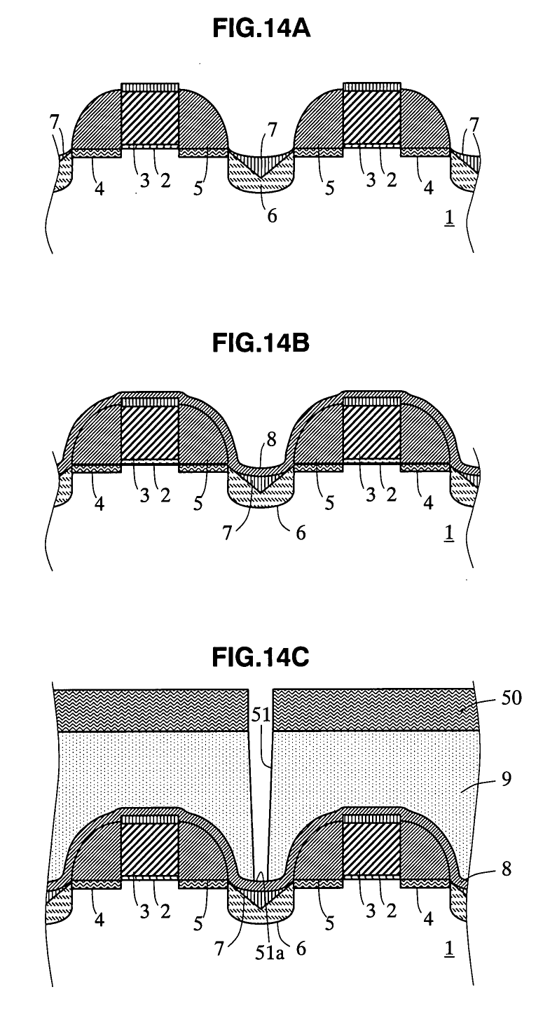

FIGS. 14A to 14C are sectional views showing a manufacturing process of a semiconductor device in Embodiment 5 of the present invention.

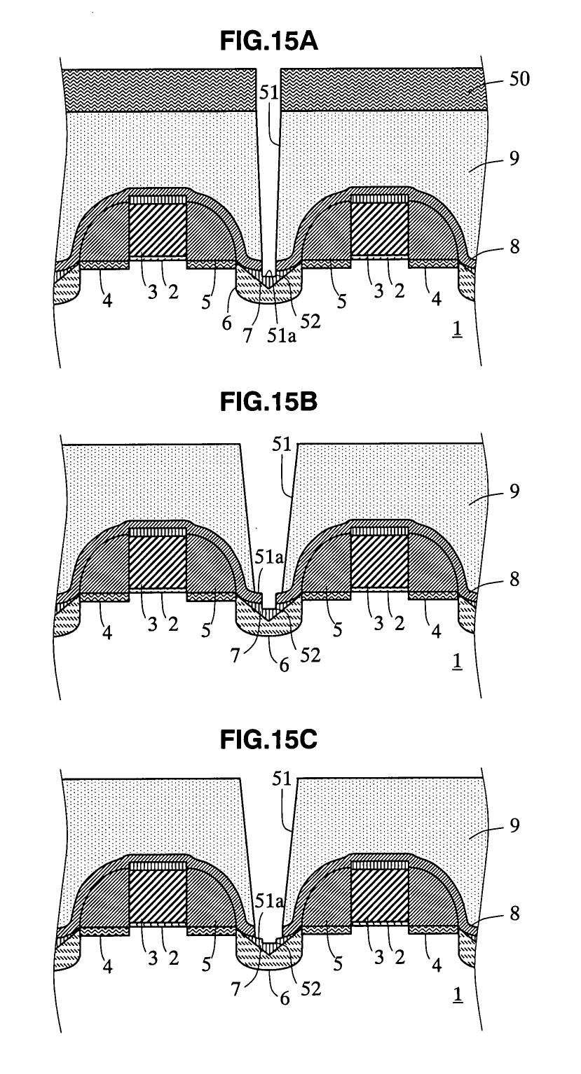

FIGS. 15A to 15C are sectional views showing a manufacturing process of a semiconductor device in Embodiment 5 of the present invention.

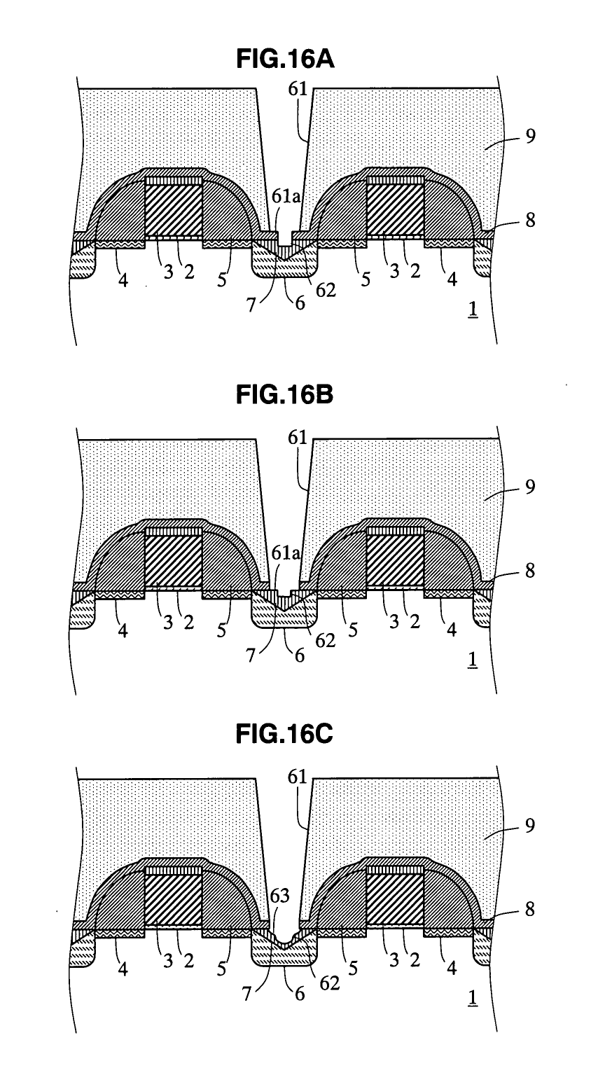

FIGS. 16A to 16C are sectional views showing a manufacturing process of a semiconductor device in Embodiment 6 of the present invention.

FIGS. 17A to 17C are sectional views showing a manufacturing process of a prior semiconductor device.

FIG. 18 is a graph showing a relationship between the etching amount of contact bottom and the silicide area ratio of contact bottom.

FIG. 19 is a graph showing a relationship between the silicide area ratio of contact bottom and the contact resistance.

### DETAILED DESCRIPTION OF PREFERRED EMBODIMENTS

The present invention is described in detail hereafter with reference to drawings on the basis of cases wherein the present invention is applied to a semiconductor device formed with two transistors in regions on a semiconductor substrate divided by element isolation. In each embodiment, contact plugs electrically connected to a high-concentration impurity diffusion region via a metal silicide layer are connected to a common drain region arranged between gate electrodes of each transistor. Although the same contact plugs are also formed in the source region of each transistor, a graphical representation and a description of the contact plug connected to the source region are omitted. Moreover, same symbols are attached to same elements as FIGS. 17A to 17C in the following drawings. Each drawing is a schematic drawing, and the vertical-horizontal dimension ratio is not strictly reflected in the drawings.

### Embodiment 1

FIGS. 1A to 1C, 2A to 2C, 3A to 3C, 4A and 4B are sectional views showing manufacturing processes of a semiconductor device in Embodiment 1 of the present invention.

First, element isolation (non-illustrated) is formed by STI method, etc. on a semiconductor substrate 1 made of silicon, etc. Next, a gate insulating film 2 consisting of a silicon oxide film or silicon oxynitride film, etc. is formed in a film thickness of about 2 nm by RTP (Rapid Thermal Process), etc. Successively, a polysilicon film is deposited in a film thickness of about 150 nm by CVD method, etc. on the semiconductor substrate 1. Two gate electrodes 3 are formed by applying the well-known lithographic technique and etching technique to said gate insulating film 2 and the polysilicon film. Moreover, gate electrode materials are not restricted to polysilicon, and other materials such as silicon compounds, tungsten, titanium, aluminum, etc. can be used.

Then, a p-type impurity, such as boron, etc., is ion-implanted into the semiconductor substrate 1, e.g., with an implantation energy of about 3 keV and with the gate electrode 3 as a mask. Thereby, a shallow low-concentration impurity diffusion region 4 of about 20 nm in depth as an extension region is formed (FIG. 1A).

Successively, an insulating film consisting of a silicon nitride film of about 60 nm in film thickness is deposited on the semiconductor substrate 1. As shown in FIG. 1B, sidewall spacers 5 are formed on both sides of the gate electrodes 3 by performing anisotropic etching, such as argon spatter etching, etc., to the insulating film. Successively, a p-type impurity, such as boron, etc., is ion-implanted with implantation energy of, say, 40 keV and with the gate electrodes 3 and the sidewall spacers 5 as a mask. Thereby, a deep high-concentration impurity diffusion region 6 of about 100 nm in depth functioning as a source region and a drain region is formed as shown in FIG. 1B.

Subsequently, as shown in FIG. 1C, a nickel silicide layer 7 is formed at the surface of the high-concentration impurity diffusion region 6 and the upside of the gate electrodes 3 in a self-aligning manner by the well-known salicide process. As described above, the nickel silicide layer 7 becomes the shape of an inverted triangle in case the spacing of the gate electrodes 3 is narrow, which a distance between the sidewall spacers 5 is 140 nm or less.

After the nickel silicide layer 7 is formed, as shown in FIG. 2A, a stopper film 8 (first insulating film) functioning as an etching stopper is formed on the semiconductor substrate 1 in a contact hole forming process described later. Here, a silicon nitride film of about 30 nm in film thickness is deposited as the stopper film 8 by CVD method. The stopper film 8 may also function as an etching stopper and may also be constructed by other material films such as silicon carbide film, etc.

An insulating film 9 (second insulating film) consisting of a silicon oxide film, a BPSG (Boro-Phospho Silicate Glass) film, a PSG (Phospho Silicate Glass) film, etc. is formed in a film thickness of about 700 nm by CVD method, etc. The upside of the insulating film 9 is flattened by CMP method or etch-back method. A photoresist is coated on the insulating film 9, then photolithography is performed and a resist pattern 10 having an opening at a contact hole formation position is formed (FIG. 2B).

In this embodiment, the diameter of opening of the resist pattern 10 is designed in such a size that the thickness of the nickel silicide layer 7 becomes within an adequately thick region. Namely, it becomes such a diameter that the high-concentration impurity diffusion region 6 is not exposed to the bottom of the contact hole when the nickel silicide layer 7 under the stopper film 8 is over-etched in an etching process of the stopper film 8 described later. In this embodiment, the diameter of opening of the resist pattern 10 is about 70 nm.

Successively, a contact hole 11 (through hole) is formed in the insulating film 9 by an anisotropic etching with the resist pattern 10 as a mask (FIG. 2C). The etching is carried out in a state in which the insulating film 9 can be etched selectively for the stopper film 8.

Accordingly, the etching stops in a state that the stopper film 8 exposes to a bottom 11a of the contact hole 11. The above etching may be performed, e.g., by introducing C₅F₈ gas, O₂ gas and Ar gas into a two-frequency parallel-plate type RIE (Reactive Ion Etching) apparatus. Here, the flow rate of each gas is 15 mL/min (standard state, represented as sccm hereafter) for C₅F₈ gas, 18 sccm for O₂ gas and 950 sccm for Ar gas. The internal pressure in an etching chamber is maintained at 6.7 Pa. A high-frequency power of 1,800 W is impressed on the upper electrode of a parallel-plate electrode and a high-frequency power of 1,500 W is impressed on the lower electrode of a parallel-plate electrode. Thereby, the contact hole 11 of about 50 nm in diameter of bottom 11a is formed.

Successively, as shown in FIG. 3A, the stopper film 8 exposed to the contact hole bottom 11a is removed by anisotropic dry etching. The etching may be performed, e.g., by introducing CHF₃ gas of 50 sccm in flow rate, O₂ gas of 20 sccm in flow rate and Ar gas of 600 sccm in flow rate into a two-frequency parallel-plate type RIE apparatus. At this time, the internal pressure in an etching chamber is maintained at 6.7 Pa, a power of 1,500 W is impressed on the upper electrode and a power of 300 W is impressed on the lower electrode, respectively.

The etching time of the etching is set to a time in which a part of the nickel silicide layer 7 under the stopper film 8 is removed with the stopper film 8, and a recess 12 is formed in the nickel silicide layer 7 by the etching. As described above, in this embodiment, the high-concentration impurity diffusion region 6 is not exposed to the contact hole bottom 11a during the over etching because the diameter of the contact hole 11 is formed in a region where the nickel silicide layer 7 has a sufficient thickness. Accordingly, only the nickel silicide layer 7 exposes to the contact hole bottom 11a after the etching (FIG. 3A).

In this embodiment, after the resist pattern 10 is removed by ashing, etc., an isotropic dry etching is performed for the insulating film 9. For example, the isotropic etching can be carried out by the above two-frequency parallel-plate type RIE apparatus. Here, an etching gas composed of C₄F₈ gas, O₂ gas and Ar gas is used. The flow rate of each gas is 15 sccm for C₄F₈ gas, 10 sccm for O₂ gas and 950 sccm for Ar gas. The internal pressure in the etching chamber is maintained at 13 Pa, a high-frequency power of 1,000 W is impressed on the upper electrode and a high-frequency power of 500 W is impressed on the lower electrode. Thereby, as shown in FIG. 3B, the diameter of insulating film 9 part of the contact hole 11 is expanded, and the stopper film 8 newly exposes to the bottom of the contact hole 11.

The stopper film 8 newly exposed in this manner is removed by dry etching again (FIG. 3C). This etching is performed in a state in which only the stopper film 8 is removed and the nickel silicide layer 7 under the stopper film 8 is almost not removed. Therefore, the high-concentration impurity diffusion region 6 does not expose by this etching. Moreover, such etching can be realized by properly setting the etching time in the same condition as the above-mentioned anisotropic etching condition for the stopper film 8 (a silicon nitride film here).

Subsequently, a conductor consisting of a laminated film of a titanium nitride film and a tungsten film is filled into the contact hole 11 by the well-known technique, and then unnecessary conductor on the insulating film 9 is removed by CMP method forming a contact plug 15 (FIG. 4A). In this embodiment, the contact plug 15 is formed in such a state that a part of its bottom is fitted to the recess 12 of the nickel silicide layer 7. Moreover, upper layer wirings 16 are formed on the contact plug 15 as shown in FIG. 4B.

As described above, in this embodiment, the contact hole 11 is formed in the region where the nickel silicide layer 7 has a sufficient thickness, and a part of the nickel silicide layer 7 is removed in a range where the high-concentration impurity diffusion region 6 is not exposed to the contact hole bottom 11a. Then, the diameter of the contact hole 11 is expanded by etching in a state in which only the insulating film 9 can be etched selectively and isotropically, and the stopper film 8 newly exposed to the contact hole bottom 11a is removed. Therefore, this embodiment enables inhibiting the exposure of the high-concentration impurity diffusion region 6 at the contact hole bottom 11a occurring in prior art and ensure the contact area of the contact plug 15 and the nickel silicide layer 7 at the same time. Moreover, a stabilized contact resistance may be obtained because the recess 12 is formed by over-etching the nickel silicide layer 7.

If necessary, upper structures such as other wiring layers, etc. are formed on the semiconductor substrate 1 formed with the upper layer wirings 16, thus the formation of the semiconductor device finishes.

As described above, this embodiment enables inhibiting the exposure of the high-concentration impurity diffusion region 6 at the contact hole bottom 11a during the etching for forming the contact hole and ensure the contact area with the contact hole bottom 11a. This enables forming a low-resistance contact in a good yield.

### Embodiment 2

In the above embodiment 1, a technique wherein the contact hole and the recess of the nickel silicide layer 7 are formed in the region where the nickel silicide layer 7 has a sufficient thickness and then the diameter of the contact hole is expanded was described. However, the same structure as the contact hole of Embodiment 1 may also be formed by other techniques. FIGS. 5A to 5C, 6A to 6C, 7A and 7B are sectional views showing manufacturing processes of a semiconductor device in Embodiment 2 of the present invention.

In this embodiment, a stopper film 8 of about 30 nm in film thickness consisting of a silicon nitride film or a silicon carbide film, etc. is formed on a semiconductor substrate 1 formed with transistors via the same processes as the processes shown in FIGS. 1A to 1C and 2A (FIG. 5A). Then, as shown in FIG. 5B, an insulating film 9 of about 700 nm in film thickness consisting of a silicon oxide film, a BPSG film or a PSG film, etc. is formed by CVD method on the stopper film 8, and the upside of the insulating film 9 is flattened by CMP method or etch-back method, etc. A photoresist is coated on the insulating film 9, then photolithography is performed and a resist pattern 20 having an opening at a contact hole formation position is formed. In this embodiment, the diameter of opening of the resist pattern 20 is about 100 nm.

Successively, as shown in FIG. 5C, a contact hole 21 passing through the insulating film 9 is formed by an anisotropic etching with the resist pattern 20 as a mask. The etching is carried out in a state in which the insulating film 9 may be etched selectively for the stopper film 8. Accordingly, the etching stops in a state that the stopper film 8 exposes to the bottom of the contact hole 21. In the case of this embodiment, the bottom diameter of the contact hole 21 becomes about 80 nm. For example, the conditions exemplified in the anisotropic etching process of the insulating film in the above Embodiment 1 (FIG. 2C) may be used in the etching.

Successively, after the resist pattern 20 is removed by ashing, etc., as shown in FIG. 6A, an insulating film 23 capable of selectively etching for the insulating film 9 is deposited in a film thickness of about 10 nm by CVD method. In this embodiment, the insulating film 9 is a silicon nitride film, and the insulating film 23 is a silicon oxide film.

An anisotropic etching, such as argon spatter etching, etc., is performed for the insulating film 23. The anisotropic etching is stopped at a time that the insulating film 23 deposited on the insulating film 9 is etching removed. Thereby, as shown in FIG. 6B, a spacer 24 is formed at the inner wall of the contact hole 21.

Next, as shown in FIG. 6C, the stopper film 8 is etched with the spacer 24 as a mask. For example, the etching may be performed in the condition exemplified by the anisotropic etching process of the stopper film in the above Embodiment 1 (FIG. 3A). The etching time of the etching is set to a time in which a part of the nickel silicide layer 7 under the stopper film 8 is removed with the stopper film 8. Accordingly, a recess 22 is formed in the nickel silicide layer 7 by the etching. In this embodiment, the diameter of the contact hole bottom 21a is controlled to 50 nm by the above spacer 24. Namely, the high-concentration impurity diffusion region 6 is not exposed to the contact hole bottom 21a during the over etching because the diameter of the contact hole bottom 21a is set within a region where the nickel silicide layer 7 has a sufficient thickness. Accordingly, only the nickel silicide layer 7 exposes to the contact hole bottom 21a after the etching.

Successively, the spacer 24 is removed by etching. The etching can be carried, e.g., by using an etching gas composed of CHF₃ gas and O₂ gas in a parallel-plate type RIE apparatus. Here, CHF₃ gas of 50 sccm in flow rate and O₂ gas of 30 sccm in flow rate are introduced in such a state that the pressure inside an etching chamber is maintained at 10 Pa, and a high-frequency power of 300 W is impressed on a lower electrode. The stopper film 8 covered by the spacer 24 exposes to the contact hole bottom 21a by the etching (FIG. 7A). A contact hole 21 where only the nickel silicide layer 7 exposes to the bottom 21a is formed by removing the exposed stopper film 8 (FIG. 7B). Moreover, the etching of the stopper film 8 is performed in a state in which only the stopper film 8 is removed and the nickel silicide layer 7 under the stopper film 8 is almost not removed. Therefore, the high-concentration impurity diffusion region 6 does not expose due to the etching. Such an etching can be realized by properly setting an etching time in the same condition as the above-mentioned anisotropic etching of the stopper film 8.

Although a graphical representation is omitted, subsequently a conductor consisting of a laminated film of a titanium nitride film and a tungsten film is similarly filled as Embodiment 1, and then unnecessary conductor on the insulating film 9 is removed by CMP method forming a contact plug. And, upper layer wirings are further formed on the conductor.

As described above, in this embodiment, the diameter of the contact hole bottom 21a is controlled to the region where the nickel silicide layer 7 has a sufficient thickness by forming the contact hole 21 of a larger diameter and then forming the spacer 24 at the inner wall of the contact hole 21. Then, a part of the nickel silicide layer 7 may be removed in a range where the high-concentration impurity diffusion region 6 is not exposed to the contact hole bottom 21a by etching removing the stopper film 8 in the state. And, after the spacer 24 is removed, the stopper film 8 newly exposed to the contact hole bottom 21a is removed. Therefore, this embodiment enables inhibiting the exposure of the high-concentration impurity diffusion region 6 to the contact hole bottom 21a occurring in prior art and ensure the contact area of the contact plug and the nickel silicide layer 7 at the same time. Moreover, a stabilized contact resistance may be obtained because the recess 22 is formed by over-etching the nickel silicide layer 7.

If necessary, upper structures such as other wiring layers, etc. are formed on the semiconductor substrate 1 formed with the upper layer wirings, thus the formation of the semiconductor device finishes.

As described above, this embodiment enables inhibiting the exposure of the high-concentration impurity diffusion region at the contact hole bottom during the etching for forming the contact hole and ensure the contact area with the contact hole bottom. This enables forming a low-resistance contact in a good yield.

### Embodiment 3

In the above embodiments, the one-step recess is formed in the metal silicide layer, but the recess may also be constructed in multiple steps. FIGS. 8A to 8C, 9A and 9B are sectional views showing manufacturing processes of a semiconductor device in Embodiment 3 of the present invention.

In this embodiment, first, a contact hole 31 of about 50 nm in bottom diameter and a recess 32 of the nickel silicide layer 7 are formed on a semiconductor substrate 1 formed with transistors via the same processes as the processes shown in FIGS. 1A to 1C and 2A to 2C and 3A (FIG. 8A). Then, an insulating film 9 and a stopper film 8 are isotropically etched in a condition of no selectivity. The etching may be carried out, e.g., by introducing CHF₃ gas of 50 sccm in flow rate and O₂ gas of 30 sccm in flow rate into an etching chamber at 15 Pa and impressing a high-frequency power of 120 W on a lower electrode in a parallel-plate RIE apparatus. Thereby, the diameter of the contact hole 31 is expanded as shown in FIG. 8B.

Next, as shown in FIG. 8C, an etching of the nickel silicide layer 7 exposed to the bottom 31a of the contact hole 31 is performed by anisotropic etching as shown in FIG. 8C. The etching may be carried out, e.g., by introducing C₄F₈ gas of 5 sccm in flow rate and O₂ gas of 20 sccm in flow rate into an etching chamber at 6.7 Pa and impressing a high-frequency power of 1,000 W on a lower electrode in a parallel-plate RIE apparatus. Thereby, a recess 32 of two-step structure is formed in the nickel silicide layer 7.

Successively, the isotropic etching shown in FIG. 8B is carried out once again, and the diameter of the contact hole 31 is expanded (FIG. 9A). Then, the etching shown in FIG. 8C is carried out once again, and the etching of the nickel silicide layer 7 exposed to the contact hole bottom 31a is performed (FIG. 9B). By the above processes, the surface of the nickel silicide layer 7 exposed to the contact hole bottom 31a is fabricated in steps to form a recess 32 having multi-step structure. Moreover, the number of replicating the expansion of the diameter of the contact hole and the etching of the nickel silicide layer is not specially restricted, and the number of replications is optional in a range in which the high-concentration impurity diffusion region 6 is not exposed to the contact hole bottom 31a.

Although a graphical representation is omitted, subsequently a conductor consisting of a laminated film of a titanium nitride film and a tungsten film is similarly filled into the contact hole 31 as Embodiments 1 and 2, and then unnecessary conductor on the insulating film 9 is removed by CMP method forming a contact plug. And, upper layer wirings are further formed on the conductor.

As described above, in this embodiment, the contact hole 31 is formed in a region where the nickel silicide layer 7 has a sufficient thickness, and a part of the nickel silicide layer 7 is removed in a range where the high-concentration impurity diffusion region 6 is not exposed to the contact hole bottom 31a. Then, the etching is performed in a state in which an isotropic etching without selectivity between the insulating film 9 and the stopper film 8 is possible, and the diameter of the contact hole 31 is expanded. Subsequently, the nickel silicide layer 7 is etched by an anisotropic etching with the contact hole 31 as a mask. Moreover, a stepwise recess 32 with the initially etched region as the most inferior region is formed at the surface of the nickel silicide layer 7 by alternately repeating the isotropic etching for expanding the diameter of the contact hole 31 and the anisotropic etching for etching the nickel silicide layer 7. Therefore, this embodiment enables inhibiting the exposure of the high-concentration impurity diffusion region at the contact hole bottom occurring in prior art and ensure the contact area of the contact plug and nickel silicide layer at the same time. Moreover, a stabilized contact resistance may be obtained because the recess 32 is formed by etching the nickel silicide layer 7.

If necessary, upper structures such as other wiring layers, etc. are formed on the semiconductor substrate 1 formed with the upper layer wirings, thus the formation of the semiconductor device finishes.

As described above, like the above Embodiments 1 and 2, this embodiment enables inhibiting the exposure of the high-concentration impurity diffusion region at the contact hole bottom during the etching for forming the contact hole and ensure the contact area with the contact hole bottom. This enables forming a low-resistance contact in a good yield.

### Embodiment 4

In the above embodiments, each recess is formed in the nickel silicide layer by etching with the contact hole formed in the insulating film 9 as a mask. In this embodiment, a technique for forming a recess of the metal silicide layer by using a mask pattern formed on a semiconductor substrate in place of the contact hole is described. FIGS. 10A to 10C, 11A to 11C, 12A and 12B are sectional views showing manufacturing processes of a semiconductor device in Embodiment 4 of the present invention.

In this embodiment, first, as shown in FIG. 10A, an insulating film 43, such as a silicon nitride film, etc., is deposited in a film thickness of about 20 nm by CVD method on a semiconductor substrate 1 formed with transistors via the same process as the process shown in FIGS. 1A to 1C. The material of the insulating film 43 is not specially restricted if it is a material capable of ensuring the selection ratio to the insulating film 9.

Next, an anisotropic dry etching, such as argon spatter etching, etc., is performed for the insulating film 43, and second sidewall spacers 44 consisting of a silicon nitride film are formed as a control pattern on the lateral surface of the sidewall spacers 5 (FIG. 10B).

Successively, a silicon nitride film as stopper film 8 is deposited in a film thickness of about 30 nm by CVD method, etc. (FIG. 10C). As shown in FIG. 11A, an insulating film 9 of about 700 nm in film thickness consisting of a silicon oxide film, etc. is formed by CVD method, etc., and the upside of the insulating film 9 is flattened by CMP method or etch-back method, etc. A photoresist is coated on the insulating film 9, then photolithography is performed and a resist pattern 40 having an opening at a the contact hole formation position is formed. In this embodiment, the diameter of opening of the resist pattern 40 is about 100 nm.

Successively, as shown in FIG. 11B, a contact hole 41 passing through the insulating film 9 is formed by an anisotropic etching with the resist pattern 40 as a mask. The etching is carried out in a state in which the insulating film 9 can be etched selectively for the stopper film 8. Accordingly, the etching stops in a state that the stopper film 8 exposes to the bottom 41a of the contact hole 41. Moreover, for example, the condition exemplified by the anisotropic etching process of the insulating film in the above Embodiment 1 (FIG. 2C) may be used for the etching.

The stopper film 8 exposed to the contact hole bottom 41a is further removed by an anisotropic dry etching. Thereby, third sidewall spacers 45 formed by the anisotropic etching of the stopper film 8 are formed on the lateral surface of the second sidewall spacers 44 (FIG. 11C). For example, it may be performed in the condition exemplified by the anisotropic etching process of the stopper film in the above Embodiment 1 (FIG. 3A).

Successively, the resist pattern 40 is removed by ashing, etc., and then the etching of the nickel silicide layer 7 exposed to the contact hole bottom 41a is performed by an anisotropic dry etching (FIG. 12A). For example, the condition exemplified by the anisotropic etching process of the nickel silicide layer 7 in Embodiment 3 (FIG. 8C) may be used for the etching. Thereby, a recess 42 is formed at the surface of the nickel silicide layer 7. In this embodiment, an opening region between the third sidewall spacers 45 is set to a size becoming a region where the nickel silicide layer 7 has a sufficient thickness. Therefore, a high-concentration impurity diffusion region 6 is not exposed to the contact hole bottom 41a in the etching.

Subsequently, as shown in FIG. 12B, the second sidewall spacers 44 and the third sidewall spacers 45 exposed to the bottom 41a of the contact hole 41 are removed, e.g., by etching in the same condition as in the above-mentioned anisotropic etching process of the stopper film 8 and the formation of the contact hole 41 finishes.

Although a graphical representation is omitted, subsequently a conductor consisting of a laminated film of a titanium nitride film and a tungsten film, etc. is similarly filled into the contact hole 41 as the above embodiments, and then unnecessary conductor on the insulating film 9 is removed by CMP method forming a contact plug. And, upper layer wirings are further formed on the conductor.

As described above, in this embodiment, the second sidewall spacers 44 for controlling the opening region of the contact hole bottom 41a to a region where the nickel silicide layer 7 has a sufficient thickness are formed on the lateral surface of the sidewall spacers 5 before the stopper film 8 and the insulating film 9 are deposited on the semiconductor substrate 1. Then, after the stopper film 8 and the insulating film 9 are formed, a region controlled by the second sidewall spacers 44 is exposed to the contact hole bottom 41a. Subsequently, an etching of the nickel silicide layer 7 is performed with the second sidewall spacers 44 as a mask, and then the second sidewall spacers 44 are removed. Therefore, this embodiment enables inhibiting the exposure of the high-concentration impurity diffusion region at the contact hole bottom 41a occurring in prior art and ensure the contact area of the contact plug and nickel silicide layer at the same time. Moreover, a stabilized contact resistance may be obtained because the recess 42 is formed by etching the nickel silicide layer 7.

If necessary, upper structures such as other wiring layers, etc. are formed on the semiconductor substrate 1 formed with the upper layer wirings, thus the formation of the semiconductor device finishes.

As described above, like the above embodiments, this embodiment enables inhibiting the exposure of the high-concentration impurity diffusion region at the contact hole bottom during the etching for forming the contact hole and ensure the contact area with the contact hole bottom. This enables forming a low-resistance contact in a good yield.

### Embodiment 5

In the above embodiments, contacts are formed on a flat semiconductor substrate 1. However, in the contact structures like the above embodiments, curved contact surfaces of the contact plug and the metal silicide layer may further increase the contact area. Accordingly, in this embodiment, a concave surface is formed at the surface of the semiconductor substrate at a contact formation position. FIGS. 13A to 13C, 14A to 14C, 15A to 15C are sectional views showing manufacturing processes of a semiconductor device in Embodiment 5 of the present invention.

In this embodiment, first, sidewall spacers 5 are formed on the semiconductor substrate 1 by the same processes as the processes shown in FIG. 1A to 1C (FIG. 13A). Next, an isotropic etching of the semiconductor substrate 1 is performed with gate electrodes 3 and the sidewall spacers 5 as a mask. Thereby, as shown in FIG. 13B, a concave curved surface 53 is formed at the surface of the semiconductor substrate 1. The isotropic etching may be performed, e.g., by wet etching. Here, a silicon substrate is etched to 20 nm with a fluoro-nitric acid (hydrofluoric acid: 0.2 wt %, nitric acid: 0.55 wt %) of 60° C. as etchant for the wet etching.

Successively, a p-type impurity such as boron, etc. is ion-implanted into the semiconductor substrate 1, e.g., with an implantation energy of 40 keV and with the gate electrodes 3 and the sidewall spacers 5 as a mask. Thereby, as shown in FIG. 13C, a deep high-concentration impurity diffusion region 6 of 100 nm in depth functioning as a source region and a drain region is formed.

Subsequently, as shown in FIG. 14A, a nickel silicide layer 7 is formed at the surface of the high-concentration impurity diffusion region 6 and the upside of the gate electrodes 3 in a self-aligning manner by the well-known salicide process. As described above, the cross-sectional shape of the nickel silicide layer 7 becomes the shape of an inverted triangle in case the spacing of the gate electrodes 3 is narrow, which the sidewall spacer distance becomes 140 nm or less.

After the nickel silicide layer 7 is formed, as shown in FIG. 14B, a silicon nitride film of about 30 nm in film thickness as stopper film 8 and an insulating film 9 of about 700 nm in film thickness consisting of a silicon oxide film are deposited. Like the above embodiments, the upside of the insulating film 9 is flattened by CMP method or etch-back method, etc. A photoresist is coated on the insulating film 9, then photolithography is performed and a resist pattern 50 having an opening at a contact hole formation position is formed. Like Embodiment 1, the diameter of opening of the resist pattern 50 is set to a size becoming a region where the nickel silicide layer 7 has a sufficient thickness. Accordingly, the high-concentration impurity diffusion region 6 is not exposed to the bottom of the contact hole in the etching process of the stopper film 8 described later.

Successively, as shown in FIG. 14C, a contact hole 51 passing through the insulating film 9 is formed by an anisotropic etching with the resist pattern 50 as a mask. The etching is carried out in a state in which the insulating film 9 can be etched selectively for the stopper film 8. Accordingly, the etching stops in a state that the stopper film 8 exposes to the bottom of the contact hole 51. This etching may be performed, e.g., in an etching condition same as the condition exemplified by the anisotropic etching process of the insulating film in Embodiment 1 (FIG. 2C).

Subsequently, as shown in FIG. 15A, the stopper film 8 exposed to the bottom 51a of the contact hole 51 is removed by an anisotropic dry etching. The etching can be carried out in the same etching condition as the anisotropic etching process of the stopper film in Embodiment 1 (FIG. 3A).

In this embodiment, unlike Embodiment 1, the stopper film 8 of the contact hole bottom 51a is removed, and then the nickel silicide layer 7 is etched to about 100 nm by an anisotropic dry etching. The etching can be carried out in a condition same as the condition exemplified in the anisotropic etching process of the nickel silicide layer in the above Embodiment 3 (FIG. 8C). Thereby, a recess 52 is formed in the nickel silicide layer 7.

Next, the resist pattern 50 is removed by ashing, etc., then an isotropic dry etching is performed for the insulating film 9 and, as shown in FIG. 15B, the diameter of the insulating film 9 part of the contact hole 51 is expanded. Thereby, the stopper film 8 newly exposes to the bottom 51a of the contact hole 51. The stopper film 8 newly exposed is removed by a dry etching in the same condition as the above-mentioned etching of the stopper film 8.

Although a graphical representation is omitted, subsequently a conductor consisting of a laminated film of a titanium nitride film and a tungsten film, etc. is similarly filled into the contact hole 51 as the above embodiments, and then unnecessary conductor on the insulating film 9 is removed by CMP method forming a contact plug. And, upper layer wirings are further formed on the conductor.

Like the above embodiments, this embodiment enables inhibiting the exposure of the high-concentration impurity diffusion region at the contact hole bottom occurring in prior art and ensure the contact area of the contact plug and nickel silicide layer at the same time. Moreover, a stabilized contact resistance may be obtained because the recess 52 is formed by etching the nickel silicide layer 7. In this embodiment, the contact area with the contact plug is expanded because the contact surface of the metal silicide layer is made into the concave curved surface by etching the semiconductor substrate 1. As a result, an even low-resistance contact may be formed.

If necessary, upper structures such as other wiring layers, etc. are formed on the semiconductor substrate 1 formed with the upper layer wirings, thus the formation of the semiconductor device finishes.

As described above, like the above embodiments, this embodiment enables inhibiting the exposure of the high-concentration impurity diffusion region at the contact hole bottom during the etching for forming the contact hole and ensure the contact area with the contact hole bottom. This enables forming an even low-resistance contact in a good yield because the contact area of the contact plug and the metal silicide layer is expanded.

### Embodiment 6

In Embodiment 5, the concave curved surface was formed on the surface of semiconductor substrate before performing silicidation, but the concave curved surface can also be formed after performing silicidation. FIGS. 16A to 16C are sectional views showing manufacturing processes of a semiconductor device in Embodiment 6 of the present invention.

In this embodiment, first, a contact hole 61 and a recess 62 are formed on a semiconductor substrate 1 formed with transistors, and the diameter of the contact hole 61 is expanded via the same processes as the processes shown in FIGS. 1A to 1C and 2A to 2C, 3A and 3B (FIG. 16A).

Next, the stopper film 8 newly exposed to bottom 61a of the contact hole 61 by the expansion of the contact hole diameter is removed by etching (FIG. 16B). For example, the etching may be performed in the condition exemplified by the anisotropic etching process of the insulating film in Embodiment 1 (FIG. 3A).

In this embodiment, a nickel silicide layer 7 is isotropically etched by wet etching in the state. Here, the nickel silicide layer 7 is etched to about 10 nm with a fluoro-nitric acid (hydro-fluoric acid: 0.2 wt %, nitric acid: 0.55 wt %) of 60° C. as an etchant. The etching is isotropically carried out with the stopper film 8 as a mask. Thereby, a concave curved surface 63 is formed at the contact surface with the contact plug (FIG. 16C).

Although a graphical representation is omitted, subsequently a conductor consisting of a laminated film of a titanium nitride film and a tungsten film, etc. is similarly filled into the contact hole 61 as the above embodiments, and then unnecessary conductor on the insulating film 9 is removed by CMP method forming a contact plug. And, upper layer wirings are further formed on the conductor.

Like the above embodiments, this embodiment enables inhibiting the exposure of the high-concentration impurity diffusion region at the contact hole bottom occurring in prior art and ensure the contact area of the contact plug and nickel silicide layer at the same time. In this embodiment, the contact area with the contact plug is expanded by etching the semiconductor substrate 1 because the contact surface of the metal silicide layer is made into the concave curved surface. As a result, an even low-resistance contact may be formed.

If necessary, upper structures such as other wiring layers, etc. are formed on the semiconductor substrate 1 formed with the upper layer wirings, thus the formation of the semiconductor device finishes.

As described above, like the above embodiments, this embodiment enables inhibiting the exposure of the high-concentration impurity diffusion region at the contact hole bottom during the etching for forming the contact hole and ensure the contact area with the contact hole bottom. This enables forming an even low-resistance contact in a good yield because the contact area of the contact plug and the metal silicide layer is expanded.

Moreover, the present invention is not restricted to the above-mentioned embodiments, various modifications and applications are possible in a range where the effects of present invention are proved. For example, a case wherein the metal silicide layer is nickel silicide layer is described as an especially suitable case in the above embodiments. However, as is understandable from the above embodiments, the present invention has an effect of making the contact area of a contact plug and a metal silicide layer larger than prior art. Namely, the present invention may be applied to all semiconductor devices provided with a contact plug which is electrically connected to a metal silicide layer independently of the material of metal silicide layer. Of course, the processes described in the above embodiments can be replaced with well-known equivalent processes.

The present invention is useful as a semiconductor device having an effect which enables to manufacture a low-resistant contact in a good yield and provided with a contact connected to a metal silicide, such as nickel silicide, etc., and method of manufacture thereof.

While the invention has been shown and described in detail, the foregoing description is in all aspects illustrative and not restrictive. It is therefore understood that numerous modifications and variations can be devised without departing from the scope of the invention.

1. A semiconductor device provide with an impurity diffusion region formed in the surface part of a semiconductor layer, a metal silicide layer formed at the surface of the impurity diffusion region and a contact plug that passes through an interlayer insulating film formed on the metal silicide layer and is electrically connected with the metal silicide layer, comprising:
a metal silicide layer having a recess at a contact surface with a contact plug; and
a contact plug having a projection fitting to the recess in a part of contact surface with the metal silicide layer.

2. The semiconductor device according to claim 1 wherein the recess has a multi-step structure.

3. The semiconductor device according to claim 1 wherein the contact surface of the metal silicide layer with the contact plug is a concave curved surface.

4. The semiconductor device according to claim 1 wherein the main component of the semiconductor layer is silicon.

5. The semiconductor device according to claim 4 wherein the interlayer insulating film has a multilayer structure formed with a second insulating film on a first insulating film and the first insulating film functions as an etching stopper during an etching for forming a through hole in the second insulating film.

6. The semiconductor device according to claim 5 wherein the second insulating film is a silicon oxide film, a boron-phosphorus doped silicon oxide film or a phosphorus doped silicon oxide film.

7. The semiconductor device according to claim 5 wherein the first insulating film is a silicon nitride film or a silicon carbide film.

8. The semiconductor device according to claim 4 wherein the metal silicide layer is a nickel silicide layer.

9. A manufacturing method of semiconductor device provided with a contact plug electrically connected to an impurity diffusion region in the surface part of a semiconductor layer via a metal silicide layer, comprising the steps of:
forming an impurity diffusion region in the surface part of a semiconductor layer;
forming a metal silicide layer in the surface part of the impurity diffusion region;
forming an interlayer insulating film on the semiconductor layer formed with the metal silicide layer;
forming a mask pattern having an opening at a contact plug formation position on the interlayer insulating film;
forming a through hole in the interlayer insulating film by etching via the mask pattern;
forming a recess in the metal silicide layer by etching via the through hole;
expanding the diameter of the through hole; and
forming a contact plug by filling a conductor into the through hole with the expanded diameter.

10. The manufacturing method of semiconductor device according to claim 9 wherein the recess is formed by the etching for forming the through hole.

11. The manufacturing method of semiconductor device according to claim 9 further comprising the step of forming spacer at the inner wall of the through hole after the forming of the through hole, and wherein
the recess is formed by etching via the through hole formed with the spacer and the diameter of the through hole is expanded by removing the spacer after the forming of the recess.

12. The manufacturing method of semiconductor device according to claim 9 wherein the forming of the recess and the expanding of the diameter of the through hole are alternately repeated and a multi-step structure is formed in the metal silicide layer.

13. The manufacturing method of semiconductor device according to claim 9 further comprising the step of forming a pattern for controlling the diameter of bottom of the through hole after the forming of the metal silicide layer, and wherein
the recess is formed by etching via the control pattern and the diameter of the through hole is expanded by removing the control pattern after the forming of the recess.

14. The manufacturing method of semiconductor device according to claim 13 wherein the control pattern is a sidewall formed at a gate electrode adjacent to the through hole.

15. The manufacturing method of semiconductor device according to claim 9 further comprising the step of forming a concave curved surface in a region including a contact surface of the contact plug at the surface of the semiconductor layer by performing an isotropic etching of the semiconductor layer before the forming of the metal silicide layer.

16. The manufacturing method of semiconductor device according to claim 15 wherein the isotropic etching is performed with the sidewall formed in a gate electrode adjacent to the through hole as a mask.

17. The manufacturing method of semiconductor device according to claim 9 further comprising the step of removing a part of the metal silicide layer by an isotropic etching via the expanded through hole after the expanding of the diameter of the through hole.

18. The manufacturing method of semiconductor device according to claim 15 wherein
the isotropic etching is a wet etching.

19. The manufacturing method of semiconductor device according to claim 9 wherein the main component of the semiconductor layer is silicon.

20. The manufacturing method of semiconductor device according to claim 19 wherein the interlayer insulating film has a multilayer structure formed with a second insulating film on a first insulating film, and the first insulating film functions as an etching stopper during the etching for forming the through hole in the second insulating film.

21. The manufacturing method of semiconductor device according to claim 20 wherein the second insulating film is a silicon oxide film, a boron-phosphorus doped silicon oxide film or a phosphorus doped silicon oxide film.

22. The manufacturing method of semiconductor device according to claim 20 wherein the first insulating film is a silicon nitride film or a silicon carbide film.

23. The manufacturing method of semiconductor device according to claim 19 wherein the metal silicide layer is a nickel silicide layer.
